(19) United States
(12) Patent Application Publication
(10) Pub. No.: US 2008/0247125 A1
(43) Pub. Date: Oct. 9, 2008

(54) Handheld Housing for Wall-Mount Controller

(76) Inventors: Dennis D. Davenport, Weatherford, TX (US); Jimmy J. Jones, Crowley, TX (US)

Correspondence Address: LAW OFFICES OF JAMES E. WALTON, PLLC, 1169 N. BURLESON BLVD., SUITE 107-328, BURLESON, TX, 76028, US

(21) Appl. No.: 12/062,128

(22) Filed: Apr. 3, 2008

Related U.S. Application Data
(60) Provisional application No. 60/921,682, filed on Apr. 3, 2007.

(51) Int. Cl. H05K 5/00

(52) U.S. Cl. 361/679

(57) ABSTRACT

An assembly for a wall-mount remote-control module includes a housing adapted to receive the wall-mount remote-control module, the housing having mounting means adapted for attaching the wall-mount remote-control module to the housing, and a means for allowing access to input controls on the wall-mount remote-control module.

### This application claims the benefit of U.S. Provisional Application No. 60/921,682, filed 3 Apr. 2007, titled “Handheld Housing for Wall-Mount Controller.”

### BACKGROUND OF THE INVENTION

1. Field of the Invention

This description relates to handheld housings for controllers.

2. Description of Related Art

Wall-mount electrical controllers, such as light switches and dimmers, have been around for many years. These controllers are designed, configured, and dimensioned to be installed into standardized electrical junction boxes. As such, these controllers have mounting brackets, tabs, and mounting holes having specific configurations and dimensions. These controllers are installed into the junction box and usually covered by standardized cover plates. The problem with these wall-mount controllers is that the user must be near the junction box to operate the electrical device.

In recent years, small handheld remote-control devices have been developed that allow users to control electrical devices, such as lights and ceiling fans, remotely. With these remote control devices, the user can operate the electrical device from anywhere within the operational range of the remote control. These remote control devices usually include a small housing and one or more self-powered internal circuit boards that are connected to input buttons and switches that can be accessed by the user. The housing and the circuit boards are designed together so that the circuit boards fit properly into the housing. The problem with these remote control devices is that the housing can only be used with its corresponding circuit boards and control circuitry.

Although the foregoing devices represent great strides in the area of electrical controllers, many shortcomings remain.

### BRIEF DESCRIPTION OF THE DRAWINGS

FIG. 1 is a top view of a handheld housing for a wall-mount controller assembly according to the preferred embodiment of the present application.

FIG. 2 is an exploded, oblique top view of the assembly of FIG. 1.

FIG. 3 is an exploded, oblique bottom view of the assembly of FIG. 1.

FIG. 4 is a top view of a handheld housing for a wall-mount controller assembly according to an alternative embodiment of the present application.

FIG. 5 is a side cross-sectional view of the assembly of FIG. 4 taken at V-V.

FIG. 6 is an end cross-sectional view of the assembly of FIG. 4 taken at VI-VI.

### DETAILED DESCRIPTION OF THE PREFERRED EMBODIMENT

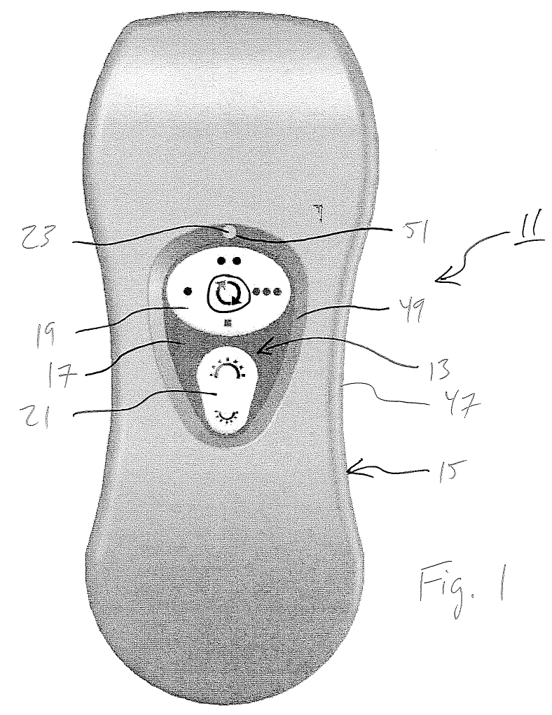

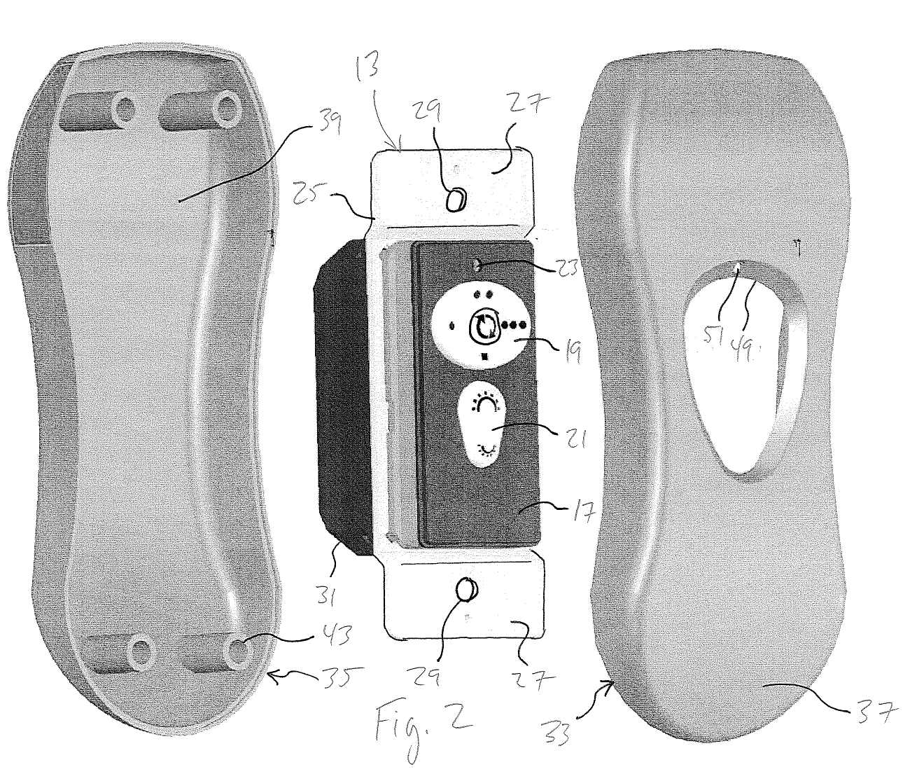

FIGS. 1-3 illustrate a remote-control assembly 11, comprising a wall-mount remote-control module 13 and a handheld housing 15. FIG. 1 shows the components assembled together, and FIGS. 2 and 3 are exploded views of assembly 11.

Referring to FIGS. 1-3, module 13 is a self-powered remote-control module configured for attachment to a standardized electrical junction box (not shown), such that a faceplate 17 is positioned to allow a user to interact with module 13. Controls, such as fan switch 19 and light switch 21, are located on faceplate 17. One or more signaling devices, such as light 23, may also be located on faceplate 17 for providing selected indications during operation. A mounting plate 25 has opposing mounting flanges 27 for attaching module 13 to the standardized electrical junction box, which is accomplished by inserting, for example, a threaded fastener through holes 29 and into a corresponding receptacle on the junction box. A switch housing 31 is located on the opposite side of mounting plate 25 from faceplate 17 for enclosing the electrical components and circuitry of module 13. Module 13 is shown with fan switch 19 and light switch 21, which may be used to wirelessly control the operation of associated electrical devices, such as a ceiling fan and an attached light. Switches 19, 21 may include provisions for on/off control and dimming/variable-speed control. Additional switches and/or functionality may be provided within wall-mount module 13. Wireless control may be accomplished through the use of radio-frequency, infra-red, or other types of wireless communication.

In the embodiment shown, handheld housing 15 comprises an upper portion 33 and a lower portion 35. Portions 33, 35 are sized to allow module 13 to be installed within a volume formed when portions 33, 35 are assembled together. Upper portion 33 has a faceplate 37, and lower portion 35 has a base plate 39. Four posts 41 protrude from an inner surface of faceplate 37, and portions 33, 35 may be assembled together by aligning portions 33, 35 and inserting each post 41 into one of four corresponding cylindrical receptacles 43, which protrude from an inner surface of base plate 39. When portions 33, 35 are assembled, faceplate 37 and base plate 39 are spaced from each other, such that a sufficient space is created for module 13 within housing 15. Module 13 is attached to upper portion 33 at mounting posts 45, which also protrude from an inner surface of faceplate 37 and correspond to the positions of holes 29 in mounting flanges 27. Module 13 may be secured to posts 45 using, for example, a threaded fastener, or module may be secured using other types of connections, such as by press fitting holes 29 onto posts 45. Alternatively, posts 45 may protrude from an inner surface of base plate 39 on lower portion 35. Another type of mounting involves inserting posts 45 into holes 29 for longitudinally and laterally locating module 13 within housing 15, while base plate 39 is used to maintain the positioning of module 13 on posts 45. When portions 33, 35 are assembled to form housing 15, housing 15 preferably has a comfortable, ergonomic shape and may have, for example, a narrowed section 47 to provide for user comfort when gripping housing 15.

When installed in housing 15, module 13 is positioned so that controls 19, 21 are visible and accessible through an aperture 49 formed in faceplate 37, and this positioning is readily seen in FIG. 1. Likewise, an aperture 51 is formed in faceplate 37 for allowing light emitted by light 23 to be visible to the user. During operation, a user grips housing 15 about narrowed section 47, which preferably positions the thumb of the user near controls 19, 21. User may then operate the associated devices by actuating controls 19, 21. In an alternative embodiment, aperture 49 may be replaced or modified by a flexible or movable cover portion that allows access to switches 19, 21.

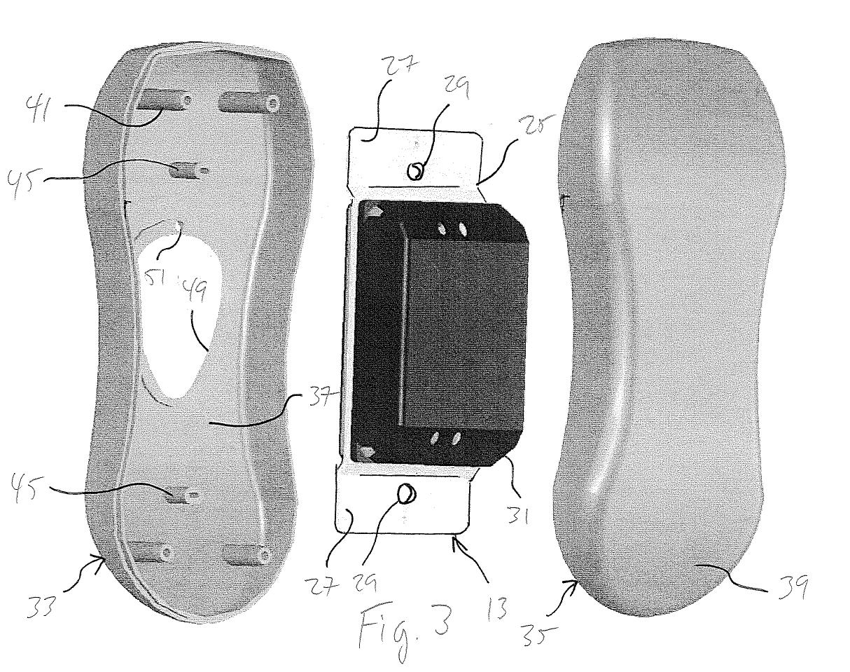

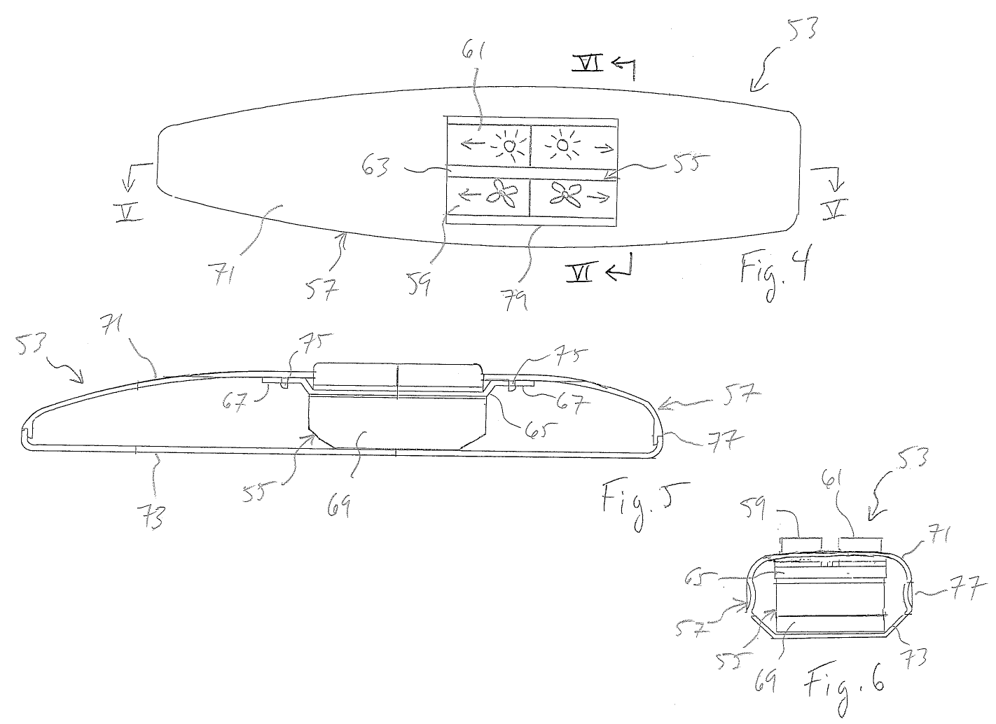

FIGS. 4-6 illustrate another embodiment of a remote-control assembly 53, comprising a wall-mount remote-control module 55 and a handheld housing 57. FIG. 4 shows assembly 53 in a top view, and FIGS. 5 and 6 are cross-sectional views of assembly 53.

Remote-control module 55 is similar in construction and function to module 13, described above, and is a self-powered remote-control module configured for attachment to a standard wall box. Controls, such as fan switches 59 and light switches 61, are located on faceplate 63, and a mounting plate 65 has opposing mounting flanges 67 for attaching module 13 to a wall box. A switch housing 69 is located on the opposite side of mounting plate 65 from faceplate 63.

Handheld housing 57 comprises an upper portion 71 and a lower portion 73, and portions 71, 73 are sized to allow module 55 to be installed within a volume formed when portions 71, 73 are assembled together. Module 55 is located within housing 57 using mounting posts 75, which protrude from an inner surface of upper portion 71 and correspond to the positions of holes in mounting flanges 67. When portions 71, 73 are assembled to form housing 57, housing 57 preferably has a comfortable, ergonomic shape to provide for user comfort when gripping housing 57. In the embodiment shown, portions 71, 73 are assembled together using a snap-fit configuration, and this is visible in the areas indicated by reference number 77.

When installed in housing 57, module 55 is positioned so that switches 59, 61 are visible and accessible through an aperture 79 formed in upper portion 71, and this positioning is readily seen in FIG. 4. During operation, a user preferably grips housing 57 and uses a thumb to actuate switches 59, 61 for operating the associated devices.

It should be noted that the module and housing of each embodiment may be sold or otherwise provided to the user separately or as a kit. One embodiment of a kit may include one remote-control module and one handheld housing, and another embodiment of a kit may include two remote-control modules and one handheld housing, allowing the user to install one module in a wall box and another module in the handheld housing. It should also be noted that each handheld housing may incorporate a weather-resistant seal or seals for allowing reliable use of the remote-control assembly in an outdoor setting. Also, though each illustrated embodiment of the handheld housing is shown as being formed from two portions, the housing may be formed as one piece that is configured for receiving the remote-control module. The invention of the present application has many benefits and advantages, including, providing the ability to use a wide variety of standardized wall-mount remote-control controllers in a handheld housing.

While illustrative embodiments have been described above, this description is not intended to be construed in a limiting sense. Various modifications and other embodiments will be apparent to persons skilled in the art upon reference to the description.

We claim:

1. An assembly for a wall-mount remote-control module, the assembly comprising:
a housing adapted to receive the wall-mount remote-control module, the housing having mounting means adapted for attaching the wall-mount remote-control module to the housing; and
a means for allowing access to input controls on the wall-mount remote-control module.

2. The assembly according to claim 1, wherein the mounting means includes one or more posts positioned at locations corresponding to standardized mounting apertures on the wall-mount remote-control module.

3. The assembly according to claim 1, wherein the housing is a multi-piece housing.

4. The assembly according to claim 1, wherein the housing is a one-piece housing.

5. The assembly according to claim 1, wherein the means for allowing access to input controls is one or more apertures in the housing aligned with input controls on the wall-mount remote-control module.

6. The assembly according to claim 1, wherein the means for allowing access to input controls is one or more cover portions disposed in the housing aligned with input controls on the wall-mount remote-control module.

7. A remote-control assembly, comprising:
a wall-mount remote-control module; and
a handheld housing having mounting means for attaching the remote-control module to the housing and access means for allowing a user to operate the remote-control module.

8. A kit for converting a wall-mount remote-control controller to a handheld remote-control controller, comprising:
a handheld housing adapted to receive the wall-mount remote-control controller, the housing having mounting means adapted for attaching the wall-mount remote-control controller to the housing; and
a means for allowing access to input controls on the wall-mount remote-control controller.
